(19) United States
(12) Patent Application Publication
(10) Pub. No.: US 2026/0324166 A1
(43) Pub. Date: Oct. 15, 2026

(54) DISPLAY DEVICE

(71) Applicant: LG Display Co., Ltd., Seoul (KR)

(72) Inventor: Sungmoo KIM, Goyang-si (KR)

(73) Assignee: LG Display Co., Ltd., Seoul (KR)

(21) Appl. No.: 19/578,539

(22) Filed: Mar. 25, 2026

(30) Foreign Application Priority Data
Apr. 9, 2025 (KR) 10-2025-0046111

(51) Int. Cl. H10H 29/851; H10H 29/37; H10H 29/80; H10H 29/85; H10H 29/855

(52) U.S. Cl. CPC H10H 29/851; H10H 29/37; H10H 29/8325; H10H 29/8517; H10H 29/8552

(57) ABSTRACT

A display device can include a substrate on which a plurality of sub pixels is defined, a plurality of light emitting elements disposed in each of the plurality of sub pixels, a black bank disposed at a boundary between the plurality of sub pixels, a transparent bank disposed on the black bank, and a plurality of light conversion layers disposed on the plurality of light emitting elements. Each of the plurality of light conversion layers can be disposed in a space formed by the transparent bank and the black bank. Accordingly, the transparent bank can be used as a partition wall separating the plurality of light conversion layers from each other.

### CROSS-REFERENCE TO RELATED APPLICATIONS

This application claims priority to Korean Patent Application No. 10-2025-0046111, filed on Apr. 9, 2025, in the Ministry of Intellectual Property of the Republic of Korea, the entire disclosure of which is expressly incorporated by reference into the present application.

### BACKGROUND

### FIELD

The present disclosure relates to a display device, and more particularly, to a display device using a light-emitting diode (LED).

### Discussion of the Related Art

Display devices used for a monitor of a computer, a TV, or a mobile phone include an organic light-emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

In addition, recently, a display device including an LED (light-emitting diode) is attracting attention as a next-generation display device. Since the LED is made of an inorganic material rather than an organic material, reliability is excellent, and a lifespan thereof is longer than that of a liquid crystal display device or an organic light-emitting display device. Further, the LED has a fast lighting speed, excellent luminous efficiency, and a strong impact resistance so that a stability is excellent and an image having a high luminance can be displayed. However, it can be difficult to implement a display device with a high resolution and a wide viewing angle because a configuration of an opaque partition wall disposed between the LEDs can be limited.

### SUMMARY OF THE DISCLOSURE

An object to be achieved by the present disclosure is to provide a display device capable of displaying a high-resolution image.

Another object to be achieved by the present disclosure is to provide a high-resolution and wide viewing angle display device.

Still another object to be achieved by the present disclosure is to provide a display device which reduces an area of each of a plurality of sub pixels.

Still another object to be achieved by the present disclosure is to provide a wide viewing angle display device.

Still another object to be achieved by the present disclosure is to provide a display device with an improved light conversion efficiency.

Still another object to be achieved by the present disclosure is to provide a display device with an improved viewing angle characteristic.

Still another object to be achieved by the present disclosure is to provide a display device with an improved efficiency of red light.

Still another object to be achieved by the present disclosure is to provide a display device capable of forming a black matrix.

Objects of the present disclosure are not limited to the above-mentioned objects, and other objects, which are not mentioned above, can be clearly understood by those skilled in the art from the following descriptions.

According to an embodiment of the present disclosure, a display device includes a substrate on which a plurality of sub pixels is defined, a plurality of light-emitting elements disposed in each of the plurality of sub pixels, a black bank disposed at a boundary between the plurality of sub pixels, a transparent bank disposed on the black bank, and a plurality of light conversion layers disposed on the plurality of light-emitting elements wherein each of the plurality of light conversion layers is disposed in a space formed by the transparent bank and the black bank. Accordingly, the transparent bank can be used as a partition wall separating the plurality of light conversion layers from each other.

Other detailed matters of the embodiments of the present disclosure are included in the detailed description and the drawings.

According to aspects of the present disclosure, it is possible to reduce the area of the plurality of sub pixels, thereby providing a high-resolution display device.

According to aspects of the present disclosure, an area of each of the plurality of sub pixels can be reduced by disposing a transparent bank that separates the light conversion layers.

According to aspects of the present disclosure, it is possible to improve the viewing angle characteristic by disposing a transparent bank on the black bank.

According to aspects of the present disclosure, it is possible to improve the viewing angle characteristic by disposing the light conversion layer and the light-emitting element close together.

According to aspects of the present disclosure, it is possible to increase the light conversion efficiency by arranging the light conversion layer and the light-emitting element close together.

According to aspects of the present disclosure, it is possible to increase the efficiency of red light by combining a blue light-emitting element with high light efficiency and a red light conversion layer.

According to aspects of the present disclosure, a black matrix can be formed by laminating color filters, and a black matrix can be formed when forming a color filter, thereby reducing manufacturing costs.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic block diagram of a display device according to an example embodiment of the present disclosure.

FIG. 2 is a partial cross-sectional view of a display device according to an example embodiment of the present disclosure.

FIG. 3 is a schematic enlarged plan view of a display area of a display device according to an example embodiment of the present disclosure.

FIG. 4 is a schematic enlarged plan view of a display area of a display device according to an example embodiment of the present disclosure.

FIG. 5 is a cross-sectional view of a display device taken along line A-A' in FIG. 3 according to an example of the present disclosure.

FIG. 6 is a schematic cross-sectional view of a display device taken along line B-B' in FIG. 3 according to an example of the present disclosure.

FIG. 7 is an enlarged plan view of a display area of a display device according to another example embodiment of the present disclosure.

FIG. 8 is a schematic cross-sectional view of a display device taken along line C-C' in FIG. 7.

FIG. 9 is a schematic cross-sectional view of a display device taken along a line similar to line B-B' in FIG. 3 according to still another example embodiment of the present disclosure.

FIG. 10 is a schematic cross-sectional view of a display device taken along a line similar to line C-C' in FIG. 7 according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise. Further, the term “can” fully encompasses all the meanings and coverages of the term “may.”

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to the drawings. All the components of each display device/apparatus according to all embodiments of the present disclosure are operatively coupled and configured.

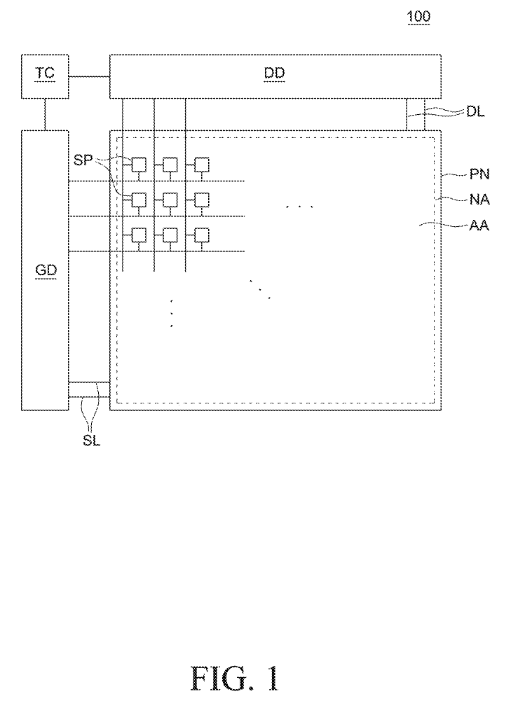

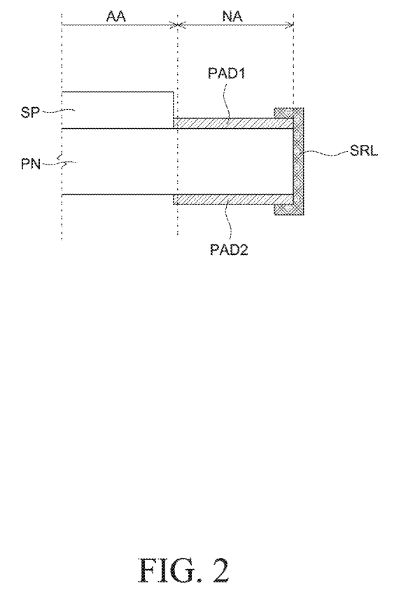

FIG. 1 is a schematic configuration diagram of a display device according to an example embodiment of the present disclosure. FIG. 2 is a partial cross-sectional view of a display device according to an example embodiment of the present disclosure. In FIG. 1, for the convenience of description, among various components of the display device 100, a display panel PN, a gate driver GD, a data driver DD, and a timing controller TC are illustrated.

Referring to FIGS. 1 and 2, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD can convert image data into a data voltage using a reference gamma voltage and supply the converted data voltage to a plurality of data lines DL.

The timing controller TC aligns image data input from the outside and supplies the image data to the data driver DD. The timing controller TC can generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub pixels SP. In the display panel PN, the plurality of scan lines SL and the plurality of data lines DL can cross each other, and the plurality of sub pixels SP can be formed at intersections of the scan line SL and the data line DL.

In the display panel PN, a display area AA (or active area) and a non-display area NA (or non-active area) can be defined.

The display area AA is an area in which images are displayed in the display device 100. In the display area AA, a plurality of sub pixels SP constituting a plurality of pixels and a pixel circuit for driving the plurality of sub pixels SP can be disposed. The plurality of sub pixels SP is a minimum unit constituting the display area AA, and n sub pixels SP can form one pixel. A pixel circuit for driving the plurality of light-emitting elements 120 can be disposed in each of the plurality of sub pixels SP. The plurality of light-emitting elements 120 can be differently defined depending on the type of the display panel PN. For example, when the display panel PN is an inorganic light-emitting display panel PN, the light-emitting element 120 can be a light-emitting element (LED) or a micro light-emitting element (LED).

In the display area AA, a plurality of signal lines for transmitting various signals to the plurality of sub pixels SP is disposed. For example, the plurality of signal lines can include a plurality of data lines DL which supplies a data voltage to each of the plurality of sub pixels SP, a plurality of scan lines SL which supplies a scan signal to each of the plurality of sub pixels SP, and the like. The plurality of scan lines SL can extend in one direction in the display area AA and be connected to the plurality of sub pixels SP, and the plurality of data lines DL can extend in a direction different from the one direction in the display area AA and be connected to the plurality of sub pixels SP. In addition, a power line PL, a reference line, and the like can be further disposed in the display area AA, but are not limited thereto.

The non-display area NA is an area where an image is not displayed and can be defined as an area extending from the display area AA. In the non-display area NA, a link line and a pad electrode for transmitting a signal to the sub pixel SP of the display area AA, or a driver IC, such as a gate driver IC or a data driver IC, can be disposed. The non-display area NA can be located on a rear surface of the display panel PN, for example, a surface on which the sub pixels SP are not disposed or can be omitted, and is not limited as illustrated in the drawing.

Meanwhile, a driver such as a gate driver GD, a data driver DD, and a timing controller TC can be connected to the display panel PN in various ways. For example, the gate driver GD can be mounted in the non-display area NA in a gate-in-panel (GIP) manner or mounted between the plurality of sub pixels SP in the display area AA in a gate-in-active area (GIA) manner.

For example, the data driver DD and the timing controller TC can be formed on a separate flexible film and the printed circuit board. Further, the display panel PN, the data driver DD, and the timing controller TC can be electrically connected by bonding the flexible film and the printed circuit board to the pad electrode formed in the non-display area NA of the display panel PN.

As another example, when the gate driver GD is mounted in the display area AA in the GIA manner, the flexible film and the printed circuit board can be bonded to the rear surface of the display panel PN and a side line SRL which connects the signal line on the front surface of the display panel PN to the pad electrode on the rear surface of the display panel PN is formed. Therefore, the non-display area NA can be minimized on the front surface of the display panel PN. Therefore, when the gate driver GD, the data driver DD, and the timing controller TC are connected to the display panel PN in the above-described manner, a zero bezel with substantially no bezel can be implemented.

In the non-display area NA of the display panel PN, a plurality of pad electrodes for transmitting various signals to the plurality of sub pixels SP is disposed. For example, a first pad electrode PAD1 for transmitting a signal to the plurality of sub pixels SP is disposed in the non-display area NA on the front surface of the display panel PN, and a second pad electrode PAD2 electrically connected to a driving component such as a flexible film and the printed circuit board is disposed in the non-display area NA on the rear surface of the display panel PN.

In this case, various signal lines connected to the plurality of sub pixels SP, for example, a scan line SL or a data line DL extend from the display area AA to the non-display area NA to be electrically connected to the first pad electrode PAD1.

Further, the sideline SRL is disposed along the side surface of the display panel PN. The sideline SRL can electrically connect the first pad electrode PAD1 on the front surface of the display panel PN and the second pad electrode PAD2 on the rear surface of the display panel PN. Therefore, a signal from the driving component on the rear surface of the display panel PN can be transmitted to the plurality of sub pixels SP through the second pad electrode PAD2, the sideline SRL, and the first pad electrode PAD1. Accordingly, a signal transmission path is formed from the front surface to the side surface and the rear surface of the display panel PN to minimize an area of the non-display area NA on the front surface of the display panel PN.

Accordingly, the driving component is connected to the rear surface of the display panel PN using the sideline SRL to reduce the area of the non-display area NA and implement the display device 100 with a minimized bezel. Further, when a plurality of display devices 100 with a minimized bezel is arranged to form a tiling display device, a seam area between one display device 100 and another adjacent display device 100 in which an image is not displayed is minimized to improve display quality.

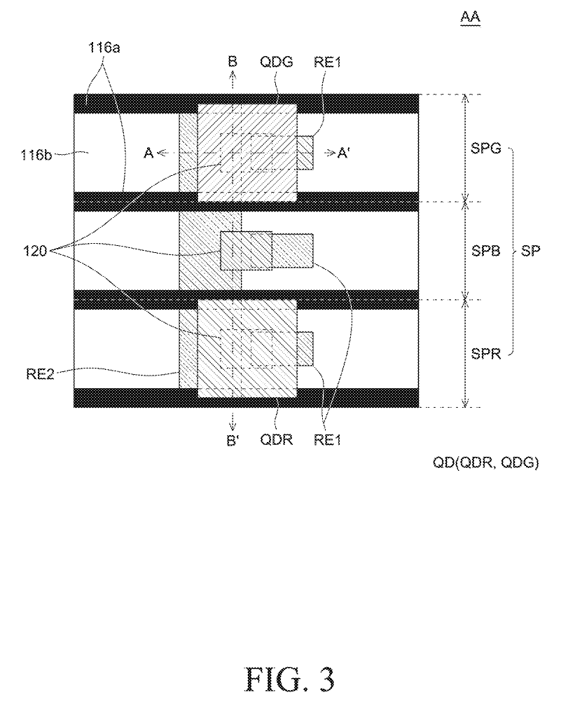

Hereinafter, a sub pixel SP of the display device 100 according to an example embodiment of the present disclosure will be described in more detail with reference to FIGS. 3 - 6.

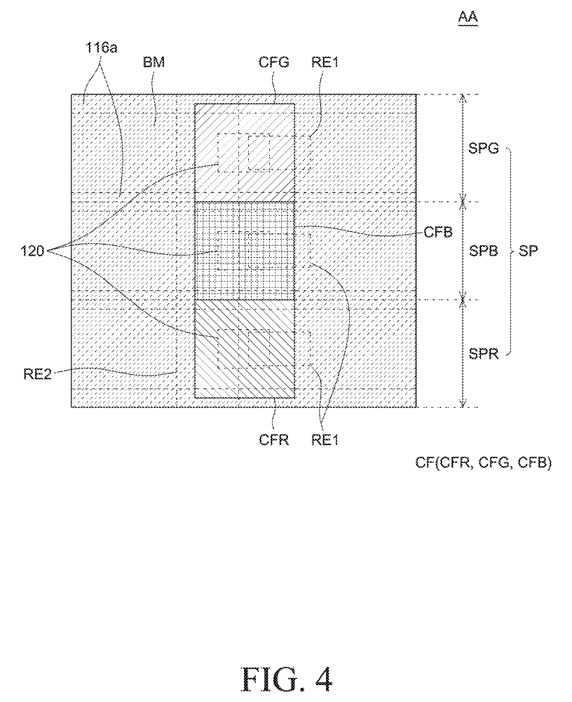

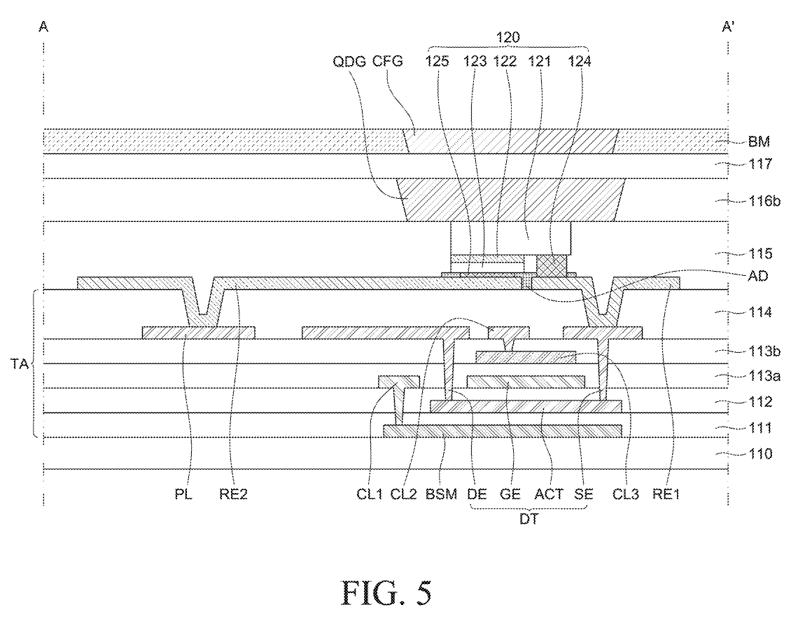

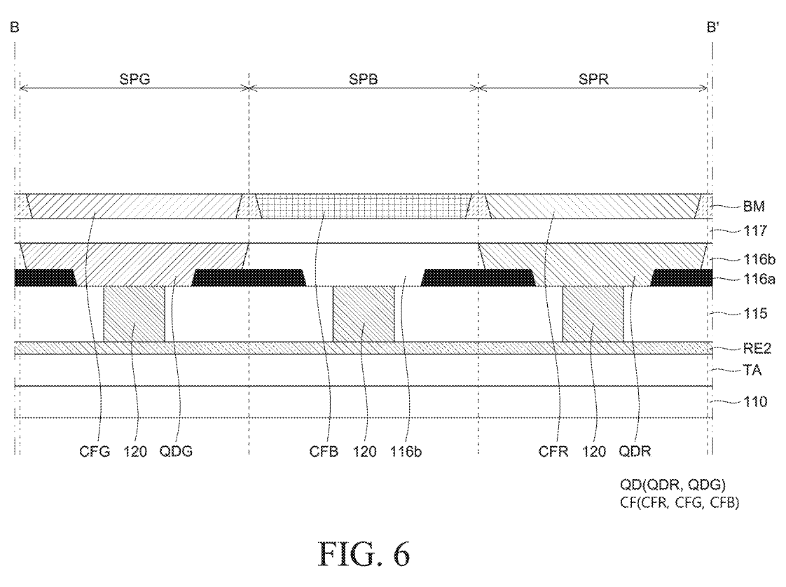

FIG. 3 is a schematic enlarged plan view of a display area of a display device according to an example embodiment of the present disclosure. FIG. 4 is a schematic enlarged plan view of a display area of a display device according to an example embodiment of the present disclosure. FIG. 5 is a cross-sectional view of a display device taken along line A-A' in FIG. 3. FIG. 6 is a schematic cross-sectional view of a display device taken along line B-B' in FIG. 3. For convenience of description, in FIG. 3, a plurality of light-emitting elements 120, a plurality of reflective electrodes RE1 and RE2, a plurality of light conversion layers QD, a black bank 116a and a transparent bank 116b are illustrated, and in FIG. 4, a plurality of light-emitting elements 120, a plurality of reflective electrodes (RE1 and RE2), a plurality of color filters CF, a black bank 116a, and a black matrix BM are illustrated, and in FIG. 6, a TFT array TA and a light-emitting element 120 are schematically illustrated.

Referring to FIGS. 3- 6, a plurality of sub pixels SP is disposed in the display area AA. Each of the plurality of sub pixels SP includes a light-emitting element 120 and can independently emit light. The plurality of sub pixels SP can be disposed in a matrix while forming a plurality of rows and a plurality of columns, but the example embodiments of the present disclosure are not limited thereto.

The plurality of sub pixels SP includes a red sub pixel SPR, a green sub pixel SPG, and a blue sub pixel SPB. Images of various colors can be displayed by a combination of red light, green light, and blue light from each of the red sub pixel SPR, the green sub pixel SPG, and the blue sub pixel SPB.

The red sub pixel SPR, the green sub pixel SPG, and the blue sub pixel SPB can be disposed on the same line. A blue sub pixel SPB can be disposed between the red sub pixel SPR and the green sub pixel SPG. The red sub pixel SPR can be disposed to be spaced apart from the green sub pixel SPG with the blue sub pixel SPB interposed therebetween, and the blue sub pixel SPB can be disposed to be adjacent to the red sub pixel SPR and the green sub pixel SPG. In order to dispose the plurality of light conversion layers QD, the blue sub pixel SPB can be disposed between the red sub pixel SPR and the green sub pixel SPG, which will be described in more detail below.

The substrate 110 is a member which supports other components of the display device 100 and can be an insulating substrate 110. For example, the substrate 110 can be made of glass, resin, or the like. Further, the substrate 110 can be made of polymer, plastic, or the like, and in some embodiments of the present disclosure, the substrate 110 can be made of a plastic material having flexibility. A plurality of sub pixels SP can be formed on the substrate 110 to display an image.

A light shielding layer BSM is disposed on the substrate 110 in each of the plurality of sub pixels SP. The light shielding layer BSM can block light incident onto an active layer ACT of the driving transistor DT to minimize a leakage current. For example, the light shielding layer BSM is disposed below the active layer ACT of the driving transistor DT to block light incident onto the active layer ACT. If light is irradiated to the active layer ACT, a leakage current is generated, which can degrade the reliability of the driving transistor DT. Accordingly, the light shielding layer BSM for blocking light is disposed on the substrate 110 to improve the reliability of the driving transistor DT. The light shielding layer BSM can be made of an opaque conductive material, such as copper (Cu), aluminum (Al), molybdenum (Mo), nickel (Ni), titanium (Ti), chromium (Cr), or an alloy thereof, but is not limited thereto.

A buffer layer 111 is disposed on the substrate 110 and the light shielding layer BSM. The buffer layer 111 is disposed to cover one surface of the substrate 110 to reduce the penetration of moisture or impurities through the substrate 110. For example, the buffer layer 111 can be configured as a single layer or multilayer made of silicon oxide (SiOx) or silicon nitride (SiNx) but is not limited thereto. The buffer layer 111 can be omitted depending on the type of substrate 110 or the type of transistor but is not limited thereto.

The driving transistor DT is disposed on the buffer layer 111 in each of the plurality of sub pixels SP. The driving transistor DT includes an active layer ACT, a gate electrode GE, a source electrode SE, and a drain electrode DE. Meanwhile, other components such as a switching transistor, a sensing transistor, an emission control transistor, and a storage capacitor, can be additionally disposed in each of the plurality of sub pixels SP, in addition to the driving transistor DT.

The active layer ACT of the driving transistor DT is disposed on the buffer layer 111. The active layer ACT can be disposed to overlap the light shielding layer BSM. The active layer ACT can be formed of a semiconductor material such as an oxide semiconductor, amorphous silicon, or polysilicon, but is not limited thereto. Further, active layers of other transistors, such as a switching transistor, a sensing transistor, and an emission control transistor, can also be formed of a semiconductor material, such as an oxide semiconductor, amorphous silicon, or polysilicon, but are not limited thereto. In addition, the active layers ACT of the driving transistor DT, the switching transistor, the sensing transistor, and the emission control transistor can be formed of the same material or different materials.

A gate insulating layer 112 is disposed on the active layer ACT. The gate insulating layer 112 is an insulating layer which insulates the active layer ACT from the gate electrode GE. For example, the gate insulating layer 112 can be configured by a single layer or a double layer of silicon oxide (SiOx) or silicon nitride (SiNx) but is not limited thereto. In this case, even though in the drawing, it is illustrated that the gate insulating layer 112 is disposed only below the gate electrode GE, the gate insulating layer 112 can be disposed on the entire surface of the substrate 110 but is not limited thereto.

The gate electrode GE is disposed on the gate insulating layer 112. The gate electrode GE can be disposed to overlap the active layer ACT. The gate electrode GE can be configured by a conductive material such as copper (Cu), aluminum (Al), molybdenum (Mo), nickel (Ni), titanium (Ti), chromium (Cr), or an alloy thereof, but is not limited thereto.

A first interlayer insulating layer 113a and a second interlayer insulating layer 113b are disposed on the gate electrode GE. In the first interlayer insulating layer 113a and the second interlayer insulating layer 113b, a contact hole through which the source electrode SE and the drain electrode DE are connected to the active layer ACT is formed. The first interlayer insulating layer 113a and the second interlayer insulating layer 113b are insulating layers which protect components therebelow and can be configured by a single layer or a double layer of silicon oxide (SiOx) or silicon nitride (SiNx) but are not limited thereto.

The source electrode SE and the drain electrode DE are disposed on the second interlayer insulating layer 113b. The source electrode SE and the drain electrode DE can be electrically connected to the active layer ACT through contact holes formed in the first interlayer insulating layer 113a, the second interlayer insulating layer 113b, and the gate insulating layer 112. Any one of the source electrode SE and the drain electrode DE can be electrically connected to the light-emitting element 120. For example, any one of the source electrode SE and the drain electrode DE can supply a driving current to the light-emitting element 120 through the first reflective electrode RE1. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

A first conductive layer CL1 is disposed on the gate insulating layer 112. The first conductive layer CL1 is an electrode for applying a constant voltage to the light shielding layer BSM and can be electrically connected to the light shielding layer BSM through contact holes of the gate insulating layer 112 and the buffer layer 111. For example, the light shielding layer BSM is connected to the first conductive layer CL1 so as not to operate as a floating gate and the threshold voltage fluctuation of the driving transistor DT due to the floated light shielding layer BSM can be prevented. The first conductive layer CL1 can be formed of a conductive material, such as copper (Cu), aluminum (Al), molybdenum (Mo), nickel (Ni), titanium (Ti), chromium (Cr), or an alloy thereof, but is not limited thereto.

A second conductive layer CL2 is disposed on the second interlayer insulating layer 113b, and a third conductive layer CL3 which is electrically connected to the second conductive layer CL2 is disposed between the first interlayer insulating layer 113a and the second interlayer insulating layer 113b. The second conductive layer CL2 and the third conductive layer CL3 can be disposed to overlap the gate electrode GE of the driving transistor DT to form a capacitor with the gate electrode GE of the driving transistor DT. Accordingly, various conductive layers such as the second conductive layer CL2 and the third conductive layer CL3 are disposed on the substrate 110 to form a capacitor. The second conductive layer CL2 and the third conductive layer CL3 can be configured by a conductive material such as copper (Cu), aluminum (Al), molybdenum (Mo), nickel (Ni), titanium (Ti), chrome (Cr), or an alloy thereof, but are not limited thereto.

The power line PL is disposed on the second interlayer insulating layer 113b. The power line PL can be configured to transmit a power voltage to the light-emitting element 120 of the plurality of sub pixels SP. The power line PL can be made of a conductive material, for example, copper (Cu), aluminum (Al), molybdenum (Mo), nickel (Ni), titanium (Ti), chromium (Cr), or an alloy thereof, but is not limited thereto. The power line PL can be electrically connected to the plurality of light-emitting elements 120 through the second reflective electrode RE2. The power line PL can be configured as either a low potential power line or a high potential power line depending on the configuration of the pixel circuit.

A first insulating layer 114 is disposed on the driving transistor DT, the power line PL, and the second interlayer insulating layer 113b. The first insulating layer 114 can planarize an upper portion of the pixel circuit including the driving transistor DT. The first insulating layer 114 can be configured as a single layer or multilayer and made of any one of benzocyclobutene or an acrylic organic material or an inorganic material such as silicon oxide (SiOx) or silicon nitride (SiNx) but is not limited thereto.

Meanwhile, a portion, such as the driving transistor DT, the power line PL, and the plurality of conductive layers (CL1, CL2, and CL3), in which a circuit for driving the sub pixel SP and a line are disposed, can also be defined as the TFT (thin film transistor) array TA. For example, components disposed in an area between the substrate 110 and the first insulating layer 114 can be included in the TFT array TA. For example, the light shielding layer BSM, the driving transistor DT, the plurality of conductive layers (CL1, CL2 and CL3), the power line PL, and the insulating layers (e.g., 111, 112, 113a, 113b and 114) disposed above and below the light shielding layer BSM can be referred to as a TFT array TA.

The first reflective electrode RE1 and the second reflective electrode RE2 are disposed on the first insulating layer 114. The first reflective electrode RE1 and the second reflective electrode RE2 are electrodes for connecting each of the driving transistor DT and the power line PL to the light-emitting element 120. In addition, the first reflective electrode RE1 and the second reflective electrode RE2 can be reflective plates that reflect light, which is directed toward the substrate 110, among light from the light-emitting element 120, toward the upper side of the light-emitting element 120.

The first reflective electrode RE1 is an electrode which reflects light-emitted from the light-emitting element 120 toward the upper side of the substrate 110 and electrically connects the light-emitting element 120 and the driving transistor DT.

The second reflective electrode RE2 is an electrode which reflects light emitted from the light-emitting element 120 toward the upper side of the substrate 110 and electrically connects the light-emitting element 120 and the power line PL. At this time, the second reflective electrode RE2 connected to the power line PL commonly connected to the plurality of sub pixels SP can be commonly disposed in the plurality of sub pixels SP. For example, the plurality of sub pixels SP can share the second reflective electrode RE2.

The first reflective electrode RE1 and the second reflective electrode RE2 can include various conductive layers in consideration of light reflection efficiency and resistance. For example, the first reflective electrode RE1 and the second reflective electrode RE2 can include an opaque conductive layer such as silver (Ag), aluminum (Al), molybdenum (Mo), titanium (Ti), or an alloy thereof, and a transparent conductive layer such as indium tin oxide (ITO), but the configuration of the first reflective electrode RE1 and the second reflective electrode RE2 are not limited thereto.

A conductive adhesive layer AD is disposed on the plurality of first reflective electrodes RE1 and the second reflective electrode RE2. The conductive adhesive layer AD can be formed on the front surface of the substrate 110 to fix the light-emitting element 120 disposed on the conductive adhesive layer AD and electrically connect the light-emitting element 120 to the first reflective electrode RE1 and the second reflective electrode RE2.

The conductive adhesive layer AD can be an adhesive layer in which conductive balls are dispersed in an insulating base member. When heat or pressure is applied to the conductive adhesive layer AD, the conductive balls are electrically connected in a portion applied with heat or pressure to have a conductive property, and the conductive balls may not be electrically connected in an area which is not heated or pressurized to have an insulating property. Therefore, the conductive adhesive layer AD has a conductive characteristic only under the electrode of the light-emitting element 120 by applying heat or pressure after transferring the light-emitting element 120 onto the conductive adhesive layer AD, such that first and second electrodes 124 and 125 of the light-emitting element 120 can be electrically connected to the first reflective electrode RE1 and the second reflective electrode RE2, respectively.

The light-emitting element 120 is disposed on the conductive adhesive layer AD in each of the plurality of sub pixels SP. The light-emitting element 120 is an inorganic light-emitting element 120 that emits light by a driving current supplied to the light-emitting element 120. The light-emitting element 120 can be any one of a light-emitting diode (LED) or a micro light-emitting diode (micro LED), but the example embodiments of the present disclosure are not limited thereto.

Meanwhile, in the display device 100 according to the example embodiment of the present disclosure, images of various colors can be displayed by a combination of the light-emitting element 120 emitting blue light, the red-light conversion layer QDR, and the green light conversion layer QDG. Therefore, hereinafter, it is assumed that the light-emitting element 120 of the display device 100 according to the example embodiment of the present disclosure is a blue light-emitting element 120.

The light-emitting element 120 includes a first semiconductor layer 121, an emission layer 122, a second semiconductor layer 123, a first electrode 124, and a second electrode 125.

The second semiconductor layer 123 is disposed on the first reflective electrode RE1 and the second reflective electrode RE2, and the first semiconductor layer 121 is disposed on the second semiconductor layer 123. The first semiconductor layer 121 and the second semiconductor layer 123 can be semiconductor layers doped with p-type and n-type impurities. For example, the first semiconductor layer 121 and the second semiconductor layer 123 can be layers doped with p-type and n-type impurities into a material such as gallium nitride (GaN), indium aluminum phosphide (InAlP), or gallium arsenide (GaAs). The p-type impurity can be magnesium (Mg), zinc (Zn), beryllium (Be), and the like, and the n-type impurity can be silicon (Si), germanium(Ge), tin (Sn), and the like, but not limited thereto.

The emission layer 122 is disposed between the first semiconductor layer 121 and the second semiconductor layer 123. The emission layer 122 can emit light based on a driving current supplied to the light-emitting element 120. For example, the emission layer 122 can emit blue light, and the light-emitting element 120 can be a blue light-emitting element 120. The emission layer 122 can be formed by a single layer or a multi-quantum well (MQW) structure, and for example, can be formed of indium gallium nitride (InGaN) or gallium nitride (GaN), but is not limited thereto.

The first electrode 124 is disposed below the first semiconductor layer 121. The first electrode 124 can be in contact with a lower surface of the first semiconductor layer 121. The first electrode 124 is an electrode for electrically connecting the light-emitting element 120 to the first reflective electrode RE1 and the driving transistor DT. The light-emitting element 120 can be electrically connected to the driving transistor DT through the first electrode 124 and the first reflective electrode RE1. The first electrode 124 can be formed of an opaque conductive material, such as titanium (Ti), gold (Au), silver (Ag), copper (Cu), or an alloy thereof, a transparent conductive material, such as indium tin oxide (ITO) or indium zinc oxide (IZO), or a combination of the opaque conductive material and the transparent conductive material but is not limited thereto.

The second electrode 125 is disposed below the second semiconductor layer 123. The second electrode 125 can be in contact with the lower surface of the second semiconductor layer 123. The second electrode 125 is an electrode for electrically connecting the light-emitting element 120 to the power line PL. The light-emitting element 120 can be electrically connected to the power line PL through the second electrode 125 and the second reflective electrode RE2. The second electrode 125 can be formed of an opaque conductive material, such as titanium (Ti), gold (Au), silver (Ag), copper (Cu), or an alloy thereof, a transparent conductive material such as indium tin oxide (ITO) or indium zinc oxide (IZO), or a combination of the opaque conductive material and the transparent conductive material but is not limited thereto.

Meanwhile, a protective layer can be disposed to surround the first semiconductor layer 121, the emission layer 122, and the second semiconductor layer 123. The protective layer can protect the first semiconductor layer 121, the emission layer 122, and the second semiconductor layer 123. For example, the protective layer can be formed of an insulating material such as silicon oxide (SiOx) or silicon nitride (SiNx), but is not limited thereto.

A second insulating layer 115 is disposed on the first reflective electrode RE1 and the second reflective electrode RE2 and encloses the plurality of light-emitting elements 120. The second insulating layer 115 can be disposed to surround side portions of the plurality of light-emitting elements 120. The second insulating layer 115 can be configured as a single layer or multilayer and made of benzocyclobutene or an acrylic-based organic material, for example. However, the present disclosure is not limited thereto.

The black bank 116a is disposed between the plurality of sub pixels SP on the second insulating layer 115. Particularly, the black bank 116a is directly disposed on the second insulating layer 115 so as to reduce a vertical distance between the black bank 116a and the light-emitting element 120. The black bank 116a can be disposed along a boundary between the plurality of sub pixels SP. The black bank 116a can prevent light of each of the plurality of sub pixels SP from being mixed with each other. The black bank 116a can minimize crosstalk caused by mixing light of the plurality of sub pixels SP.

The thickness of the black bank 116a can be smaller than the thickness of the light conversion layer QD. The black bank 116a can be formed to have a minimum thickness to reduce color mixture and crosstalk. The height of the black bank 116a is formed to be lower than the light conversion layer QD to implement the wide viewing angle display device 100 and reduce the area of the sub pixel SP to implement the high-resolution display device 100. It is possible to prevent light emitted from the light-emitting element 120 and directed toward the wide viewing angle area from being blocked by the black bank 116a and thus not directed toward the wide viewing angle area. For example, the black bank 116a has a smaller height than the light conversion layer QD and the transparent bank 116b, thereby avoiding shielding of light directed toward the wide viewing angle area. Further, even though the gap between the black bank 116a and the light-emitting element 120 is formed to be narrower, the light emitted from the light-emitting element 120 is easily directed to the wide viewing angle area due to the low height of the black bank 116a. Therefore, it is possible to implement the display device 100 having a wide viewing angle and a high resolution by reducing the height of the black bank 116a.

The transparent bank 116b is disposed between the plurality of sub pixels SP on the second insulating layer 115 and the black bank 116a. Further, the transparent bank 116b can extend to some sub pixels SP where the light conversion layer QD is not disposed to cover the light-emitting element 120. For example, in the blue sub pixel SPB in which the blue light-emitting element 120 is disposed, the transparent bank 116b can be disposed on the second insulating layer 115 and the light-emitting element 120. The transparent bank 116b can be disposed in the blue sub pixel SPB so as to cover a part of the black bank 116a and the light-emitting element 120 and can be in contact with the side surface of the light conversion layer QD material of the adjacent red and green sub pixels SPR and SPG but is not limited thereto. For example, the light conversion layers QD can be disposed in all the sub pixels SP depending on a color design of the display device. For convenience of description, the sub pixels in which the transparent bank 116b is disposed can be referred to as a first group sub pixels, and the sub pixels in which the light conversion layer QD is disposed can be referred to as a second group of sub pixels.

Meanwhile, the transparent bank 116b can be made of an organic material having hydrophobic properties. The transparent bank 116b having hydrophobic properties pushes out the material of the light conversion layer QD so that the material of the light conversion layer QD is not disposed on the transparent bank 116b, but is disposed in an area between the transparent banks 116b, for example, an area of the sub pixels SP. Further, when the material of the light conversion layer QD is formed, some of the material of the light conversion layer QD applied on the transparent bank 116b due to an error flow from the transparent bank 116b to be disposed in the area of the sub pixel SP.

The plurality of light conversion layers QD is disposed on the second insulating layer 115 in the remaining sub pixels SP among the plurality of sub pixels SP. The plurality of light conversion layers QD includes a light conversion material such as a quantum dot, a nano phosphor, or an organic phosphor to convert light emitted from the light-emitting element 120 into light of various colors.

The plurality of light conversion layers QD include a green light conversion layer QDG and a red light conversion layer QDR. In the red sub pixel SPR, the red light conversion layer QDR is disposed on the second insulating layer 115 so as to cover a part of the black bank 116a and the light-emitting element 120 and in contact with the side surface of the transparent bank 116b disposed in the adjacent blue sub pixel SPB, and in the green sub pixel SPG, the green-light conversion layer QDG is disposed on the second insulating layer 115 so as to cover a part of the black bank 116a and the light-emitting element 120 and in contact with the side surface of the transparent bank 116b disposed in the adjacent blue sub pixel SPB. Accordingly, an image can be displayed by a combination of blue light from the blue light-emitting element 120 and green light converted by the green-light conversion layer QDG and red light converted by the red-light conversion layer QDR.

Meanwhile, the general red light-emitting element has lower light emission efficiency than the blue light-emitting element 120. Therefore, in the display device 100 according to the example embodiment of the present disclosure, the blue light-emitting element 120 with high light-emitting efficiency and the red light-conversion layer QDR are disposed together in the red sub pixel SPR to improve the red-light efficiency.

The transparent bank 116b is disposed between the red-light conversion layer QDR and the green light conversion layer QDG. The red-light conversion layer QDR or the green light conversion layer QDG can be filled in a space formed by the transparent bank 116b and the black bank 116a. The transparent bank 116b can separate each of the plurality of light conversion layers QD together with the black bank 116a. A space in which the red-light conversion layer QDR and the green light conversion layer QDG are disposed can be partitioned with a transparent bank 116b and a black bank 116a. Each of the plurality of light conversion layers QD can be disposed to be spaced apart from each other with the transparent bank 116b interposed therebetween.

In order to separate the plurality of light conversion layers QD from each other, the thickness of the transparent bank 116b can be equal to or thicker than the thickness of the light conversion layer QD. The top surface of the transparent bank 116b can be disposed to be equal to or higher than the top surface of the light conversion layer QD. The transparent bank 116b can be disposed to surround the light conversion layer QD at a height equal to or larger than the height of the light conversion layer QD in direct contact with the side surface of the light conversion layer QD.

The transparent bank 116b can have a tapered shape. Specifically, the transparent bank 116b can have a trapezoidal shape in which the width decreases as the cross-sectional shape goes from bottom to top. Further, each of the plurality of light conversion layers QD formed in the space between the tapered transparent banks 116b can have a reverse tapered shape. The width of the space between the tapered transparent banks 116b can increase from the bottom to the top, and accordingly, the plurality of light conversion layers QD filled in the space can be formed in a reverse tapered shape. Each of the plurality of light conversion layers QD can have an inverted trapezoidal shape in which the width increases as the cross-sectional shape goes from bottom to top.

A third insulating layer 117 is disposed on the transparent bank 116b and the plurality of light conversion layers QD. The third insulating layer 117 can protect a plurality of light conversion layers QD. The third insulating layer 117 can provide a flat surface on the plurality of light conversion layers QD and the transparent bank 116b. The third insulating layer 117 can be formed of any one of an organic insulating material and an inorganic insulating material.

A plurality of color filters CF are disposed on the third insulating layer 117. The plurality of color filters CF can overlap the plurality of sub pixels SP. The plurality of color filters CF includes a red color filter CFR, a green color filter CFG, and a blue color filter CFB. The red color filter CFR can overlap the red sub pixel SPR, the green color filter CFG can overlap the green sub pixel SPG, and the blue color filter CFB can overlap the blue sub pixel SPB. Light from the plurality of light conversion layers QD and the light-emitting element 120 can pass through the plurality of color filters CF and is extracted to the outside of the display device 100. On the other hand, external light incident on the display device 100 is absorbed by the plurality of color filters CF and is not reflected back to the outside of the display device 100. Therefore, the color filter CF which absorbs external light and transmits only the light of the sub pixel SP converted by the light conversion layer QD and directly emitted from the blue light-emitting element 120 to the outside of the display device 100 is disposed to improve the display quality and improve the color reproducibility.

The black matrix BM is disposed on the third insulating layer 117. The black matrix BM can be disposed between the plurality of color filters CF. The black matrix BM can shield light of each of the plurality of sub pixels SP so as not to be mixed with each other. In addition, the black matrix BM absorbs light incident from the outside to the display device 100, thereby minimizing a decrease in visibility due to the reflection of external light from the configuration inside the display device 100. The black matrix BM can be formed of a material different from that of the plurality of color filters CF. For example, the black matrix BM includes a black component and can be made of an opaque resin including a pigment, but is not limited thereto.

Conventionally, a bank-like opaque partition wall was disposed between a plurality of sub pixels, and a light conversion layer was disposed in a space at the height of the opaque partition wall. However, in that case, the opaque partition wall and the light-emitting element need to be disposed to be spaced apart from each other by a predetermined interval so that light from the light-emitting element passes through the opaque partition wall and propagates toward the wide viewing angle area. For example, light which is directed from the light-emitting element to the wide viewing angle area can be blocked by the opaque partition wall as the height of the opaque partition wall increases or the distance between the opaque partition wall and the light-emitting element decreases, and it can be difficult to propagate to the outside. Further, the light conversion efficiency can be ensured only when the thickness of the light conversion layer is formed to be above a predetermined level, so that the height of the opaque partition wall separating the plurality of light conversion layers should be formed to be equal to or higher than the height of the light conversion layer. Therefore, considering the thickness of the light conversion layer and the light directed to the wide viewing angle area, it can be difficult to implement high resolution because the thickness of the opaque partition wall is increased or the interval between the light-emitting element and the opaque partition wall is increased and the area of each of the plurality of sub pixels is increased.

Accordingly, to address these issues, in the display device 100 according to the example embodiment of the present disclosure, the black bank 116a having a height lower than the light conversion layer QD is disposed, and the transparent bank 116b separating each of the plurality of light conversion layers QD is disposed on the top of the black bank 116a. The light emitted from the light-emitting element 120 in the wide viewing angle direction can be easily directed to the outside through the transparent bank 116b. In addition, by forming the black bank 116a to be thin, the gap between the black bank 116a and the light-emitting element 120 can be narrowed, and the area of the sub pixel SP can be reduced. Accordingly, in the display device 100 according to the example embodiment of the present disclosure, the black bank 116a and the transparent bank 116b are disposed together between the plurality of light conversion layers QD to provide the display device 100 having a wide viewing angle and a high resolution.

Further, in the display device 100 according to the example embodiment of the present disclosure, the light conversion layer QD is directly disposed on the light-emitting element 120 to reduce a distance between the light-emitting element 120 and the light conversion layer QD and improve the light conversion efficiency. As the distance between the light-emitting element 120 and the light conversion layer QD becomes closer, the light conversion efficiency can be improved.

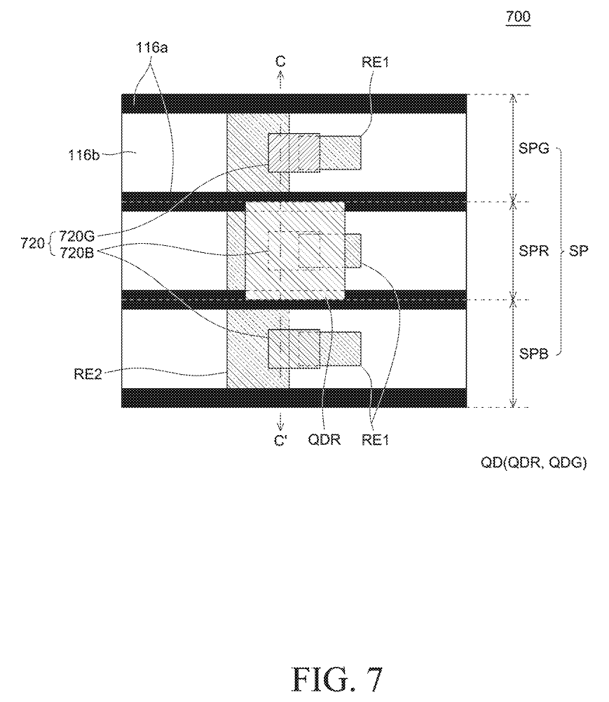

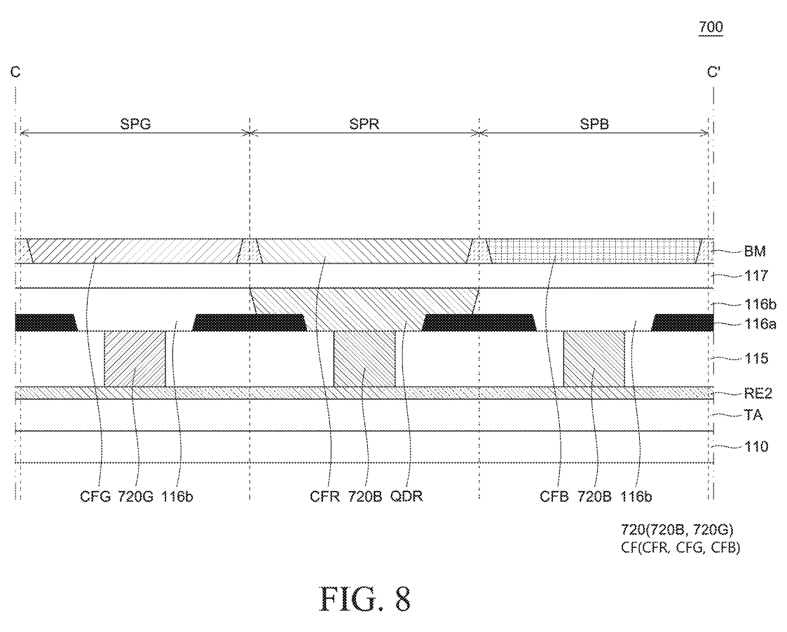

FIG. 7 is an enlarged plan view of a display area of a display device according to another example embodiment of the present disclosure. FIG. 8 is a schematic cross-sectional view of a display device taken along line C-C’ in FIG. 7. One or only difference between a display device 700 of FIGS. 7 and 8 and the display device 100 of FIGS. 1 - 6 is a configuration of a plurality of sub pixels SP, a light-emitting element 720, and a light conversion layer QD, but the other configuration is substantially the same, so that a redundant description will be omitted or may be briefly provided.

Referring to FIGS. 7 and 8, the plurality of sub pixels SP includes a red sub pixel SPR, a green sub pixel SPG, and a blue sub pixel SPB. The red sub pixel SPR, the green sub pixel SPG, and the blue sub pixel SPB can be disposed side by side on the same line. In this case, the red sub pixel SPR can be disposed between the green sub pixel SPG and the blue sub pixel SPB. The red sub pixel SPR can be disposed adjacent to any one of the green sub pixel SPG and the blue sub pixel SPB. In order to dispose the light conversion layer QD in the red sub pixel SPR, the red sub pixel SPR can be disposed between the green sub pixel SPG and the blue sub pixel SPB in which the transparent bank 116b is disposed.

The plurality of light-emitting elements 720 includes a blue light-emitting element 720B and a green light-emitting element 720G. The blue light-emitting element 720B is disposed in the blue sub pixel SPB and the red sub pixel SPR, and the green light-emitting element 720G is disposed in the green sub pixel SPG.

The light conversion layer QD includes a red light conversion layer QDR. The red light conversion layer QDR can be disposed on the second insulating layer 115 and the blue light-emitting element 720B in the red sub pixel SPR to convert blue light into red light. However, the light conversion layer QD does not need to be disposed in the green sub pixel SPG in which the green light-emitting element 720G is disposed and the blue sub pixel SPB in which the blue light-emitting element 720B is disposed.

Therefore, the transparent bank 116b can be disposed at the boundary between the plurality of sub pixels SP and disposed in both the green sub pixel SPG and the blue sub pixel SPB. Light from each of the green light-emitting element 720G and the blue light-emitting element 720B can pass through the transparent bank 116b as it is and propagate toward the outside of the display device 700.

Accordingly, in the display device 700 according to another example embodiment of the present disclosure, the green light-emitting element 720G is disposed in the green sub pixel SPG to improve green light efficiency. Instead of a combination of the blue light-emitting element 720B and the green light conversion layer QDG, green light can be emitted from the green light-emitting element 720G. In addition, since the red light-emitting element is less efficient than the green light-emitting element 720G and the blue light-emitting element 720B, the blue light-emitting element 720B and the red light-conversion layer QDR can be disposed in the red sub pixel SPR to ensure high light efficiency. Accordingly, the green light-emitting element 720G is disposed in the green sub pixel SPG to simplify the process of forming the green light conversion layer QDG to reduce the manufacturing cost, and the blue light-emitting element 720B having higher light efficiency than the red light-emitting element and the red light conversion layer QDR are disposed together in the red sub pixel SPR to improve the color reproduction rate.

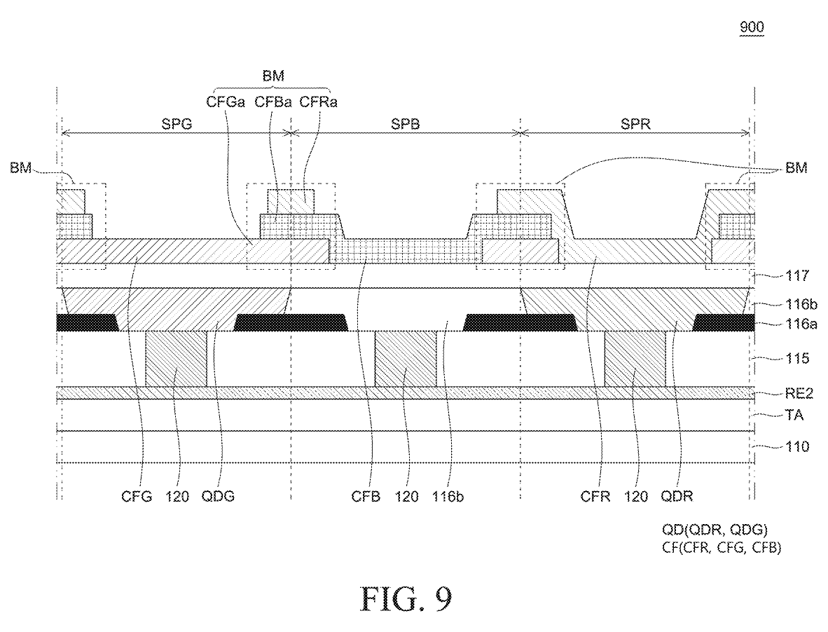

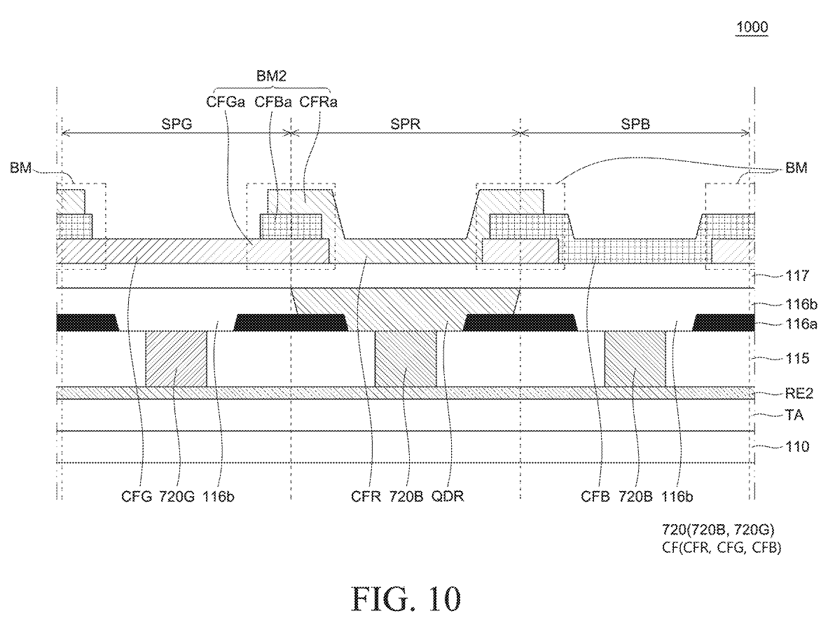

FIG. 9 is a schematic cross-sectional view of a display device taken along a line similar to line B-B' of FIG. 3 according to still another example embodiment of the present disclosure. FIG. 10 is a schematic cross-sectional view of a display device taken along a line similar to line C-C' of FIG. 7 according to still another example embodiment of the present disclosure. Each of the display devices 900 and 1000 in FIGS. 9 and 10 is substantially identical in configuration to the display device 100 in FIGS. 1 - 6 and the display device 700 in FIGS. 7 and 8, except for a black matrix BM. Therefore, repeated descriptions of the identical components will be omitted or may be briefly provided.

Referring to FIGS. 9 and 10, the black matrix BM can be formed by laminating materials of a plurality of color filters CF. For example, the black matrix BM can include a green layer CFGa formed by the same process as the green color filter CFG, a blue layer CFBa formed by the same process as the blue color filter CFB, and a red layer CFRa formed by the same process as the red color filter CFR.

A green layer CFGa can be disposed on the third insulating layer 117, a blue layer CFBa can be disposed on the green layer CFGa, and a red layer CFRa can be disposed on the blue layer CFBa. The arrangement order of the green layer CFGa, the blue layer CFBa, and the red layer CFRa can vary according to the formation order of the green color filter CFG, the blue color filter CFB, and the red color filter CFR.

The green layer CFGa, the blue layer CFBa, and the red layer CFRa disposed to overlap each other can function like the black matrix BM. Since green light transmitted through the green layer CFGa is light in a wavelength band different from those of the blue layer CFBa and the red layer CFRa, it cannot pass through the blue layer CFBa and the red layer CFRa. Likewise, blue light and red light do not pass through layers of different wavelength bands. Therefore, during the process of manufacturing the color filter CF, a part of the color filter CF is formed together in the area of the black matrix BM to form the black matrix BM.

For example, referring to the display device 900 of FIG. 9, instead of forming the black matrix BM as a black material in the same structure as the display device 100 of FIGS. 1 - 6, materials of the red color filter CFR, the green color filter CFG, and the blue color filter CFB can be stacked to form the black matrix BM.

As another example, referring to the display device 1000 of FIG. 10, the black matrix BM can be formed by laminating a plurality of color filters CF in the same structure as the display device 700 of FIGS. 7 and 8.

Accordingly, in the display devices 900 and 1000 according to still another example embodiment of the present disclosure, the black matrix BM can be replaced with the color filter CF to simplify the process of forming the black matrix BM and reduce the manufacturing cost of the display devices 900 and 1000. Since the red color filter CFR, the green color filter CFG, and the blue color filter CFB are always disposed regardless of the configurations of the light conversion layer QD and the light-emitting element 120, 720, the black matrix BM formed by stacking the plurality of color filters CF can be applied to the display devices 900 and 1000 having various structures.

The example embodiments of the present disclosure can also be described as follows:

According to an embodiment of the present disclosure, a display device includes a substrate on which a plurality of sub pixels is defined, a plurality of light-emitting elements disposed in each of the plurality of sub pixels, a black bank disposed at a boundary between the plurality of sub pixels, a transparent bank disposed on the black bank, and a plurality of light conversion layers disposed on the plurality of light-emitting elements, wherein each of the plurality of light conversion layers is disposed in a space formed by the transparent bank and the black bank.

According to another aspect of the present disclosure, each of the plurality of light conversion layers can be disposed to be spaced apart from each other with the transparent bank and the black bank interposed therebetween.

According to yet another aspect of the present disclosure, the transparent bank can have hydrophobic properties.

According to yet another aspect of the present disclosure, a thickness of the transparent bank can be equal to or thicker than a thickness of the plurality of light conversion layers.

According to yet another aspect of the present disclosure, the thickness of the transparent bank and a thickness of the plurality of light conversion layers can be thicker than a thickness of the black bank.

According to yet another aspect of the present disclosure, a part of the transparent bank can be disposed on the black bank at a boundary between the plurality of sub pixels, and the remaining part of the transparent bank can cover the plurality of light-emitting elements in a first group of sub pixels among the plurality of sub pixels.

According to yet another aspect of the present disclosure, the plurality of light conversion layers cover the light-emitting elements in a second group of sub pixels among the plurality of sub pixels, and each of the second group of sub pixels can be disposed to be spaced apart from each other with the first group of sub pixels interposed therebetween.

According to yet another aspect of the present disclosure, the plurality of light-emitting elements can be a blue light-emitting element, the first group of sub pixels can include a blue sub pixel, and the second group of sub pixels can include a red sub pixel and a green sub pixel.

According to yet another aspect of the present disclosure, the plurality of light conversion layers can include a red light conversion layer disposed in the red sub pixel, and a green light conversion layer disposed in the green sub pixel, and a transparent bank can be disposed in the blue sub pixel between the red light conversion layer and the green light conversion layer.

According to yet another aspect of the present disclosure, the plurality of light-emitting elements can include a blue light-emitting element and a green light-emitting element, the first group of sub pixels can include a blue sub pixel and a green sub pixel, and the second group of sub pixels can include a red sub pixel.

According to yet another aspect of the present disclosure, the plurality of light conversion layers can include a red light conversion layer disposed in the red sub pixel, and the transparent bank can be disposed in the blue sub pixel and the green sub pixel.

According to yet another aspect of the present disclosure, the display device can further include a plurality of color filters disposed on the plurality of light conversion layers and overlapping each of the plurality of sub pixels, and a black matrix disposed between the plurality of color filters.

According to yet another aspect of the present disclosure, the black matrix can be made of a material different from that of the plurality of color filters.

According to yet another aspect of the present disclosure, the plurality of color filters includes a red color filter, a green color filter, and a blue color filter, and the black matrix includes a red layer of the same material as the red color filter, a green layer of the same material as the green color filter, and a blue layer of the same material as the blue color filter, and the black matrix can be formed by laminating a red layer, a green layer, and a blue layer.

According to yet another aspect of the present disclosure, the transparent bank can be disposed to surround the plurality of light conversion layers by directly contacting side surfaces of the plurality of light conversion layers.

According to yet another aspect of the present disclosure, a top surface of the transparent bank can be disposed to be equal to or higher than a top surface of each of the plurality of light conversion layer.

According to yet another aspect of the present disclosure, each of the plurality of light conversion layers can be directly disposed on corresponding one of the plurality of light-emitting elements.

According to yet another aspect of the present disclosure, the black bank can be directly disposed on an insulating layer which surrounds side portions of the plurality of light-emitting elements

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure. All the technical concepts in the equivalent scope of the present disclosure should be construed as falling within the scope of the present disclosure.

What is claimed is:

1. A display device, comprising:
a substrate on which a plurality of sub pixels are defined;
a plurality of light emitting elements disposed in each of the plurality of sub pixels;
a black bank disposed at a boundary between the plurality of sub pixels;
a transparent bank disposed on the black bank; and
a plurality of light conversion layers disposed on the plurality of light emitting elements,
wherein each of the plurality of light conversion layers is disposed in a space formed by the transparent bank and the black bank.

2. The display device according to claim 1, wherein each of the plurality of light conversion layers is disposed to be spaced apart from each other with the transparent bank and the black bank interposed therebetween.

3. The display device according to claim 1, wherein the transparent bank has hydrophobic properties.

4. The display device according to claim 1, wherein a thickness of the transparent bank is equal to or greater than a thickness of one of the plurality of light conversion layers.

5. The display device according to claim 4, wherein each of the thickness of the transparent bank and the thickness of the one of the plurality of light conversion layers is greater than a thickness of the black bank.

6. The display device according to claim 1, wherein a part of the transparent bank is disposed on the black bank at a boundary between the plurality of sub pixels, and a remaining part of the transparent bank covers the light emitting elements in a first group of sub pixels among the plurality of sub pixels.

7. The display device according to claim 6, wherein the plurality of light conversion layers cover the light emitting elements in a second group of sub pixels among the plurality of sub pixels, and the second group of sub pixels are disposed to be spaced apart from each other with the first group of the sub pixels interposed therebetween.

8. The display device according to claim 7, wherein the plurality of light emitting elements include a blue light emitting element,
the first group of sub pixels include a blue sub pixel, and
the second group of sub pixels include a red sub pixel and a green sub pixel.

9. The display device according to claim 8, wherein the plurality of light conversion layers include:
a red-light conversion layer disposed in the red sub pixel; and
a green-light conversion layer disposed in the green sub pixel, and
wherein the transparent bank is disposed in the blue sub pixel between the red-light conversion layer and the green light conversion layer.

10. The display device according to claim 7, wherein the plurality of light emitting elements include a blue light emitting element and a green light emitting element,
the first group of sub pixels include a blue sub pixel and a green sub pixel, and the second group of sub pixels include a red sub pixel.

11. The display device according to claim 10, wherein the plurality of light conversion layers include a red light conversion layer disposed in the red sub pixel, and
the transparent bank is disposed in the blue sub pixel and the green sub pixel.

12. The display device according to claim 1, further comprising:
a plurality of color filters disposed on the plurality of light conversion layers and overlapping each of the plurality of sub pixels; and
a black matrix disposed between the plurality of color filters.

13. The display device according to claim 12, wherein the black matrix includes a material different from a material included in the plurality of color filters.

14. The display device according to claim 12, wherein the plurality of color filters include a red color filter, a green color filter, and a blue color filter, and
wherein the black matrix includes:
a red layer having a same material as the red color filter;
a green layer having a same material as the green color filter; and
a blue layer having a same material as the blue color filter, and
wherein the black matrix is formed by laminating the red layer, the green layer, and the blue layer.

15. The display device according to claim 4, wherein the transparent bank is disposed to surround the plurality of light conversion layers in direct contact with side surfaces of the plurality of light conversion layers.

16. The display device according to claim 4, wherein a top surface of the transparent bank is disposed to be equal to or higher than a top surface of one of the plurality of light conversion layers.

17. The display device according to claim 1, wherein each of the plurality of light conversion layers is directly disposed on a corresponding one of the plurality of light emitting elements.

18. The display device according to claim 1, wherein the black bank is directly disposed on an insulating layer which is disposed on side portions of the plurality of light emitting elements.

19. The display device according to claim 1, further comprising:
a first reflective electrode and a second reflective electrode both disposed under the plurality of light emitting elements, and configured to reflect light towards the plurality of light emitting elements.

20. The display device according to claim 19, wherein the second reflective electrode electrically connects at least one of the plurality of light emitting elements to a power line, and
wherein the plurality of sub pixels share the second reflective electrode.
